(19) United States
(12) Patent Application Publication
(10) Pub. No.: US 2023/0054793 A1
(43) Pub. Date: Feb. 23, 2023

(54) MACHINED INTERPOSER TO ENABLE LARGE SCALE HIGH FREQUENCY CONNECTIVITY

(71) Applicant: International Business Machines Corporation, Armonk, NY (US)

(72) Inventor: Muir Kumph, Croton on Hudson, NY (US)

(21) Appl. No.: 17/445,259

(22) Filed: Aug. 17, 2021

(51) Int. Cl. H01P 7/06; H01L 23/66; H01L 23/498

(52) U.S. Cl. CPC H01P 7/06; H01L 23/66; H01L 23/49838; H01L 2223/6627

(57) ABSTRACT

An apparatus comprising an interposer mounted to a conductive holder and a plurality of microwave cavities, wherein each microwave cavity of the plurality of microwave cavities is comprised of a fin section having two sidewalls, wherein each sidewall is comprised of a vane that extends up from the conductive holder through the interposer.

### STATEMENT REGARDING FEDERALLY FUNDED RESEARCH AND DEVELOPMENT

This invention was made with U.S. Government support. The U.S. Government has certain rights in this invention.

### BACKGROUND

The present invention relates generally to the field of microwave resonate management on microelectronic devices, and more particularly to designing an interposer and a holder to break up the cavity resonate frequency of the device.

FIG. 1 illustrates an electronic device 10 that includes an interposer 20 mounted in a holder 60. The interposer 20 includes a chip 30 and a plurality of coaxial connectors 40. When applying a microwave frequency to the product 10 a microwave cavity is created based on the dimensions of the holder 60 and the mounted interposer 20. The microwaves bounce between the walls of the holder 60 and the interposer 20 at a resonant frequency. At the resonant frequency the microwaves reinforce each other to form standing waves, also known as the box mode. The resonant frequency can be calculated by equations 1 to 3 below, wherein the holder 60 and the interposer 20 form a rectangular shaped cavity:

$${f}_{mnl} = \frac{c}{2 π \sqrt{{μ}_{r} {ϵ}_{r}}} \times {k}_{mnl} \qquad ( 1 )$$

$$= \frac{c}{2 π \sqrt{{μ}_{r} {ϵ}_{r}}} \times \sqrt{{( \frac{m π}{a} )}^{2} + {( \frac{n π}{b} )}^{2} + {( \frac{l π}{d} )}^{2}} \qquad ( 2 )$$

$$= \frac{c}{2 \sqrt{{μ}_{r} {ϵ}_{r}}} \times \sqrt{{( \frac{m}{a} )}^{2} + {( \frac{n}{b} )}^{2} + {( \frac{l}{d} )}^{2}} \qquad ( 3 )$$

where kₘₙₗ is the wave number, with m, n, l being mode numbers, a, b, d being the corresponding dimensions, c being the speed of light in vacuum, μᵣ and ∈ᵣ are relative permeability and permittivity of the cavity filling (the holder) respectively.

The size of the interposer 20 is dependent on the size of the chip 30 and the number of coaxial connectors 40 that are needed. As the interposer 20 increases in size, so does the holder 60 increase in size. The lowest standing frequency, i.e., box mode, is dependent on the combined dimensions of the interposer 20 and the holder 60. As the dimensions increase to accommodate larger components, then the lowest standing frequency decreases with the increased size of the interposer 20 and holder 60. For certain application the lowest standing frequency needs to be higher than the frequencies required by the chip. If the lowest standing frequency was at or near the frequencies required by the chip, then noise will develop, cross talk would occur, or other interference might occur, therefore, the lowest standing frequency, i.e., box mode, needs to be larger than the operating frequency of the components.

### BRIEF SUMMARY

Additional aspects and/or advantages will be set forth in part in the description which follows and, in part, will be apparent from the description, or may be learned by practice of the invention.

An interposer, wherein the interposer is divided into a plurality of fin sections by a plurality of grooves, wherein a fin of the plurality of fins is defined by a first groove and a second groove, wherein the fin is located between the first groove and the second groove, wherein each groove extends from the center of the interposer to an outer edge of the interposer, wherein each groove exposes the ground plane of the interposer along the length of the groove. A chip mounted to the interposer and a plurality of connecters mounted on the interposer, wherein the plurality of connector electrically connected to chip, wherein at least one connector of the plurality of connectors are mounted in each of the plurality of fin sections.

An interposer mounted to a conductive holder, wherein the silicon interposer is divided into a plurality of fin sections by a plurality of groove and the conductive holder includes a first section to receive the interposer. The first section includes a plurality of vanes that extends up from the top surface of the first section within the conductive holder, wherein each vane of the plurality of vanes extends through one of the plurality of grooves.

An apparatus comprising an interposer mounted to a conductive holder and a plurality of microwave cavities, wherein each microwave cavity of the plurality of microwave cavities is comprised of a fin section having two sidewalls, wherein each sidewall is comprised of a vane that extends up from the conductive holder through the interposer.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 is related art that illustrates an interposer mounted in a holder.

FIG. 2A illustrates a first embodiment of an interposer, in accordance with an embodiment of the present invention.

FIGS. 2B and 2C illustrate different configurations for the fin of the interposer, in accordance with an embodiment of the present invention.

FIG. 3 illustrates an edge of a fin of the interposer along one of the cut grooves, in accordance with an embodiment of the present invention.

FIG. 4 illustrates a first embodiment of a holder, in accordance with an embodiment of the present invention.

FIG. 5 illustrates the interposer being inserted in the holder, in accordance with an embodiment of the present invention.

FIG. 6 illustrates the combined interposer and holder, in accordance with an embodiment of the present invention.

FIG. 7 illustrates a second embodiment of an interposer, in accordance with an embodiment of the present invention.

FIG. 8 illustrates an edge of a fin of the interposer along one of the lines of cut holes, in accordance with an embodiment of the present invention.

FIG. 9 illustrates a second embodiment of a holder, in accordance with an embodiment of the present invention.

FIG. 10 illustrates the interposer being inserted in the holder, in accordance with an embodiment of the present invention.

FIG. 11 illustrates the combined interposer and holder, in accordance with an embodiment of the present invention.

FIG. 12 illustrates the picket fence formed at an edge of a fin of the interposer mounted in the holder, in accordance with an embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and words used in the following description and claims are not limited to the bibliographical meanings, but, are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” can be understood to include any integer number greater than or equal to one, i.e. one, two, three, four, etc. The terms “a plurality” can be understood to include any integer number greater than or equal to two, i.e. two, three, four, five, etc. The term “connection” can include both an indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. The terms “about” or “substantially” are intended to include the degree of error associated with measurement of the particular quantity based upon the equipment available at the time of filing application. For example, “about” can include a range of ±8% or 5%, or 2% of a given value. In one aspect, the term “about” means within 10% of the reported numerical value. In another aspect, the term “about” means within 5% of the reported numerical value. Yet, in another aspect, the term “about” means within 10, 9, 8, 7, 6, 5, 4, 3, 2, or 1% of the reported numerical value. The terms “about” or “substantially” are intended to include the degree of error associated with measurement of the particular quantity based upon the equipment available at the time of filing application.

Reference will now be made in detail to the embodiments of the present invention, examples of which are illustrated in the accompanying drawings, wherein like reference numerals refer to like elements throughout. Embodiments of the invention are generally directed to breaking up the microwave resonant cavity of an interposer mounted to a holder in to a plurality of cavities, therefore, creating a lowest standing frequency, i.e., box mode for each cavity. This is accomplished by dividing the interposer into separate sections, wherein the holder acts as a barrier between the separate sections. Each section acts as its own microwave cavity having its own box mode, where the box mode of any individual section is higher than the box mode of the undivided interposer combined with the holder. A chip can be mounted to the interposer, or the chip can be fabricated onto the interposer. The electrical connections from the chip fan out across the interposer to connectors, for example, coaxial connectors, thus allowing the chip to be connected to a system. The interposer is divided up in to sections by separating the interposer into a plurality of fins, where each fin extends out from the center of the interposer. The holder has a section to receive the divided interposer such that a portion of the holder extends through the interposer at the locations where portions of the interposer have been removed to receive portions of the holder, such that, the holder can be connected to the ground planes (top, bottom, or other ground planes) of the interposer. The connection occurs along the dividing point of each of the fins, thus creating sidewalls for each of the fins from a portion of the holder that extends through the interposer at the dividing point. By breaking up the interposer in to fins and by connecting the holder to the edges of the fins the microwave cavity of the entire product is divided up into smaller microwave cavities. More specifically, each of the individual fins with their sidewalls form their own microwave cavity. As the microwave cavities decrease in size the box mode increases, thereby effectively increasing the box mode at all parts of the interposer. Therefore, the smaller microwave cavity of each fin has a larger standing frequency, box mode, than the box mode for the entire product having no fins.

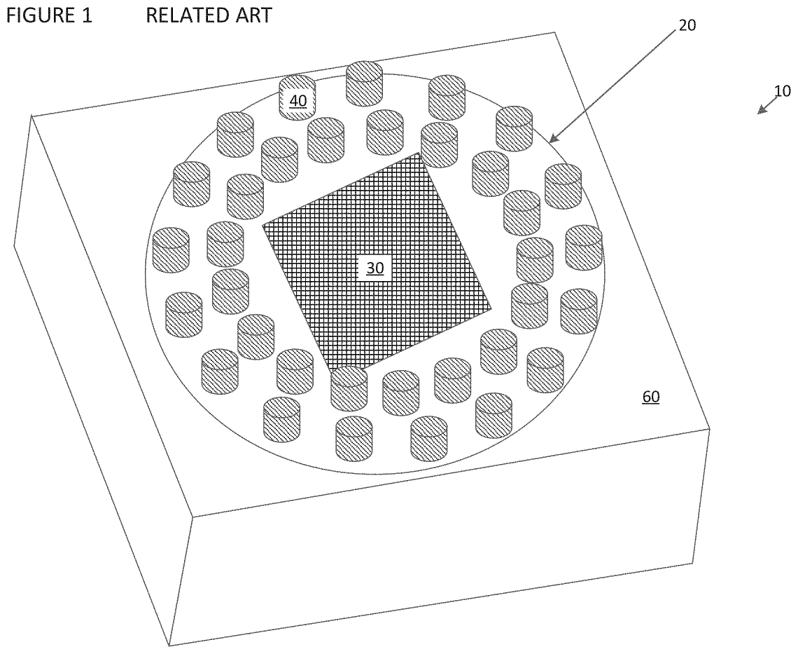

FIG. 1 is related art that illustrates an unbroken interposer 20 mounted in a holder 60. FIG. 1 illustrates an electronic product 10 that includes an interposer mounted in a holder 60. The interposer 20 includes a chip 30 and a plurality of coaxial connectors 40. The combined interposer 20 and holder 60 form only one microwave cavity. The dimensions of the combined interposer 20 and the holder 60 determines the only one lowest standing frequency, i.e., box mode, for the entire electronic product 10. Having only one box mode for the electronic product 10 limits the operating frequency of the components mounted on the chip 30 and on the interposer 20.

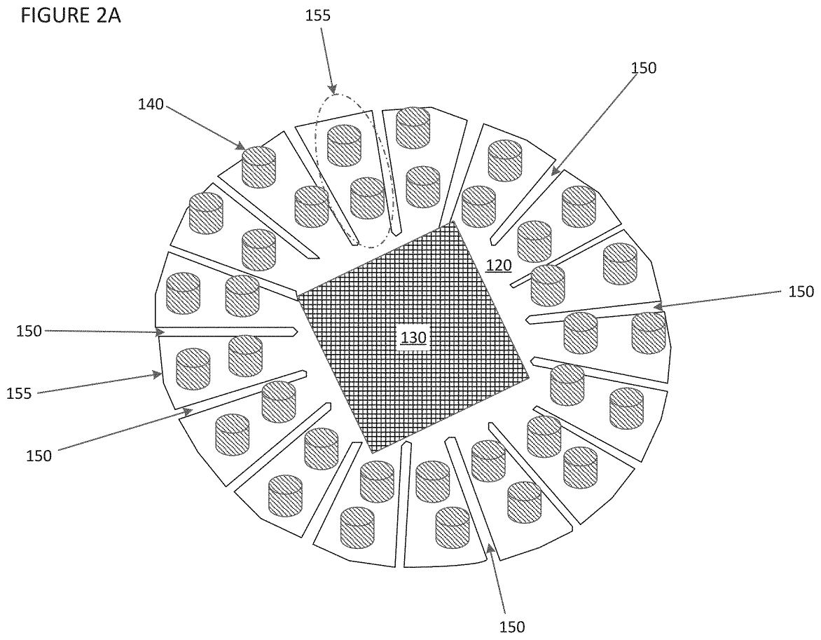

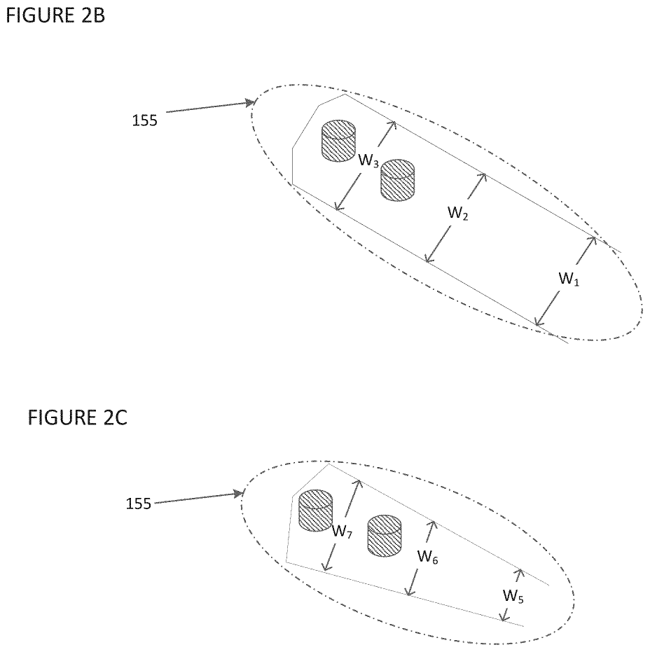

FIG. 2A illustrates a first embodiment of an interposer 120, in accordance with an embodiment of the present invention. The interposer 120 includes a chip 130 and a plurality of coaxial connectors 140. The chip 130 can include any type of electronic components in a singular amount or in a plurality of, for example, capacitors, resistors, transistors, inductors, sensors, antennas, amplifiers, attenuators, diodes, switches, fuses, Josephson junctions, memory, pins, bump bonds, CMOS device, rapid single flux quantum devices (RSFQ), lossy resonators, other types of resonators, a qubit, a Josephson Junction, or any other electrical component, or connection used in creating electrical circuits. The chip 130 can be independently fabrication, in which the different components are formed on the chip 130 prior to the chip 130 being attached on to the interposer 120. Alternatively, the chip 130 can be fabricated (i.e. forming the components) directly on the interposer 120. The chip 130 has electrical wiring/connections (not shown) that fan out from the chip 130 to the plurality of coaxial connectors 140 mounted on the interposer 120. The plurality of coaxial connectors 140 provide the necessary electronic connections to connect the chip 130 to other components located outside the chip 130/interposer 120. The connectors do not have to be coaxial connectors 140, any type of connector will be sufficient as long it provides an electronic connection from the interposer 120 to outside electrical components (not shown). The components mounted on the chip 130, the wiring (not shown) connecting to the plurality of coaxial connectors 140 can have the same operating frequency, different operating frequencies, or any combination of operating frequencies.

A plurality of grooves 150 are machined into the interposer 120. Each of the plurality of grooves 150 can pass completely through the material of the interposer 120. The interposer 120 can be comprised of any suitable material, for example, a silicon wafer. The material of the interposer 120 can be machined to have the plurality of grooves 150 after the chip 130 and the plurality of coaxial connectors 140 are mounted on the chip. The plurality of grooves 150 can be machined by using, for example, drills, water jets, or any other suitable machining process to fabricate the plurality of grooves 150. Each groove 150 is a straight path of empty space created by removal of the interposer 120 material. Each groove 150 extends from a central location of the interposer 120 to the edge of the interposer 120. The interposer 120 can have a ground plane 125 located on an exposed surface of the interposer 120, as one or more intermediate layers of the interposer 120, or combinations thereof.

The plurality of grooves 150 will create a plurality of fins 155 in the interposer 120. Each fin 155 is defined by the center of the interposer 120, two grooves 150 that are spaced apart from each other and extend from the central location of the interposer 120, and the edge of the interposer 120. Each of the fins 155 can contain zero, one, or more than one of the coaxial connectors 140. The width of each fin 155 can be constant from the central point on the interposer 120 to the edge of the interposer 120, as illustrated by FIG. 2B. The widths W₁, W₂, and W₃ are the same the width the length of the fin 155. However, the width of the fin 155 can vary, meaning that the grooves 150 extend from the central point on the interposer 120 at an angle, thus the fin 155 will be narrower towards the central point on the interposer 120 and the fin 155 will be wider towards the edge of the interposer 120, as illustrated by FIG. 2C. Width W₅ located closer to the center of the interposer 120, has a narrower width. A width W₆ located around the central portion of the fin 155 will be larger than width W₅, and the width W₇ located near the edge of the fin 155 will be larger than the width W₆. FIG. 2A illustrates that the width the fin 155 increases as the distance from the center of the interposer 120 increases, which is shown also in FIG. 2C. The width of the fin 155 is dependent on the angle/spacing of each of the grooves 150 as the grooves 150 extend out from the center of the interposer 120. FIG. 2A illustrates that the interposer 120 has a circular shape, however, the interposer 120 can be different shapers, for example, square, rectangle, ellipse, octagon, dodecagon, rhombus, or a different shape. The plurality of grooves 150 define the width of the fins 155, based on how far apart each groove 150 is from another groove 150. FIG. 2A is only meant to be an example that illustrate the present invention and is not meant to be limiting.

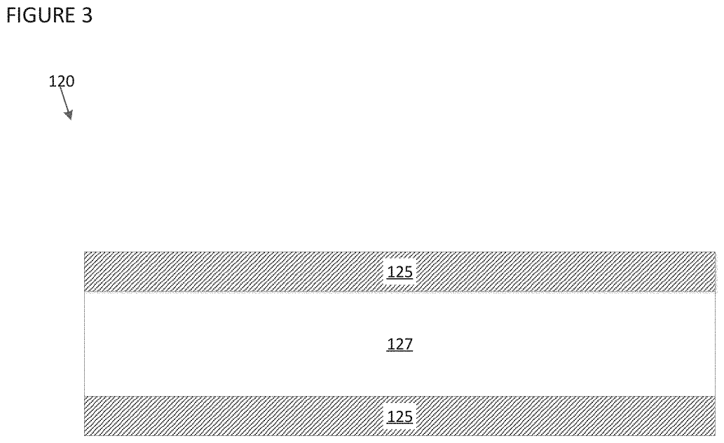

FIG. 3 illustrates an edge of a fin 155 of the interposer 120 along one of the cut grooves 150, in accordance with an embodiment of the present invention. FIG. 3 illustrates the interposer 120 that includes a substrate 127 and a ground plane 125. FIG. 3 illustrates a ground plane 125 located on top of the substrate 127 and on the bottom of the substrate 127. The location of the ground planes 125 as illustrated by FIG. 3 is only an example and it is not meant to be limiting. Each of the plurality of grooves 150 is cut through all of the layers, for example, the ground plane 125, and the substrate 127 of the interposer 120, thus exposing an edge of each of the layers of the interposer 120 along the length of each of the plurality of grooves 150. The ground plane 125 is exposed at the edge of the fin 155 by one of the plurality of grooves 150, as illustrated by FIG. 3.

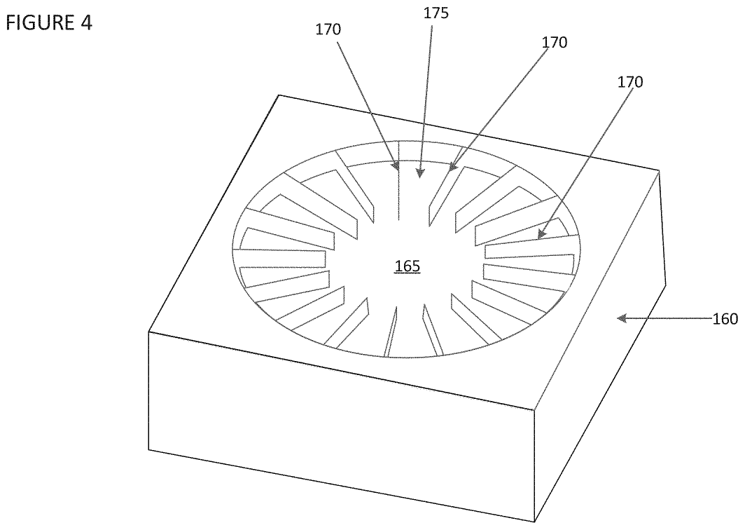

FIG. 4 illustrates a first embodiment a holder 160, in accordance with an embodiment of the present invention.

The holder 160 is comprised of a conductive material. The conductive material can be, for example, copper or any other suitable conductive material that can be physically connected to the ground plane 125 of the interposer 120. The holder includes a section 165 that receives the interposer 120, so that the interposer 120 can be mounted therein. The section 165 includes a plurality of vanes 170 that extend up vertically from the bottom of the section 165 and are attached to the sidewall of section 165. The plurality of vanes 170 can be the same material as the holder 160 or the plurality of vanes 170 can be comprises of a different material. The holder 160 can be machine by, for example, a drill, a water jet, or other suitable means, to create the section 165 and to create the plurality of vanes 170. If the plurality of vanes 170 are comprised of a different material than the holder 160, then the vanes 170 can be mounted to the section 165 of the holder 160, by any suitable means. Each of the plurality of vanes 170 of the holder 160 are designed to be aligned with one of the plurality of grooves 150 of the interposer 120. A second section 175 is defined by one of the plurality of vanes 170 on each side, such that the fin 155 of the interposer 120 will sit within the second section 175 when the interposer 120 is inserted in to the holder 160.

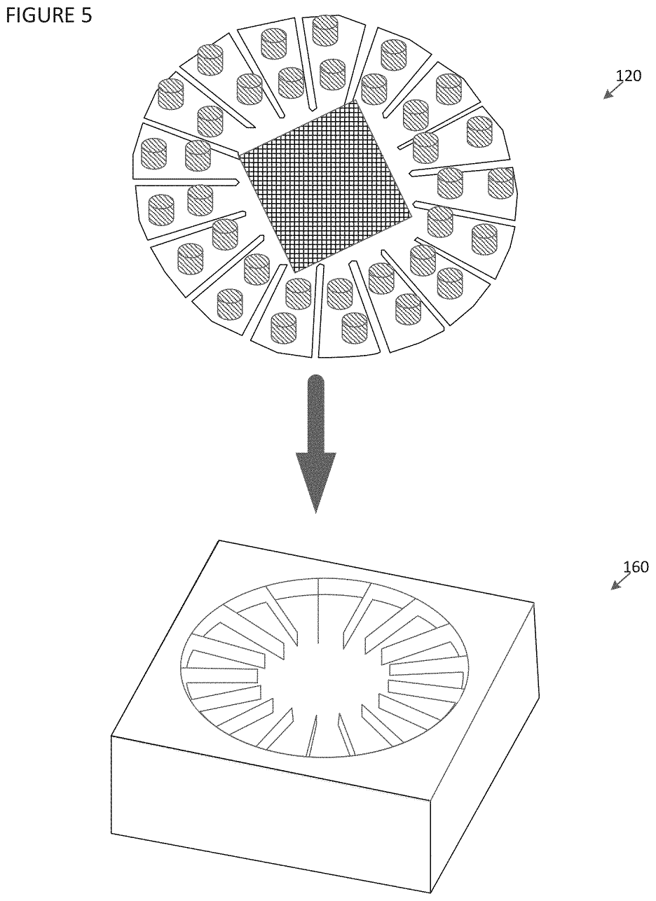

FIG. 5 illustrates the interposer 120 being inserted in the holder 160, in accordance with an embodiment of the present invention. The interposer 120 is first aligned with the holder 160, by matching each groove 150 to a correspond vane 170 in the holder 160 prior the insertion of the interposer 120 in to the holder 160. The vanes 170 of holder 160 fit in to a corresponding groove 150 in the interposer 120 as the interposer 120 is inserted into section 165 of the holder 160.

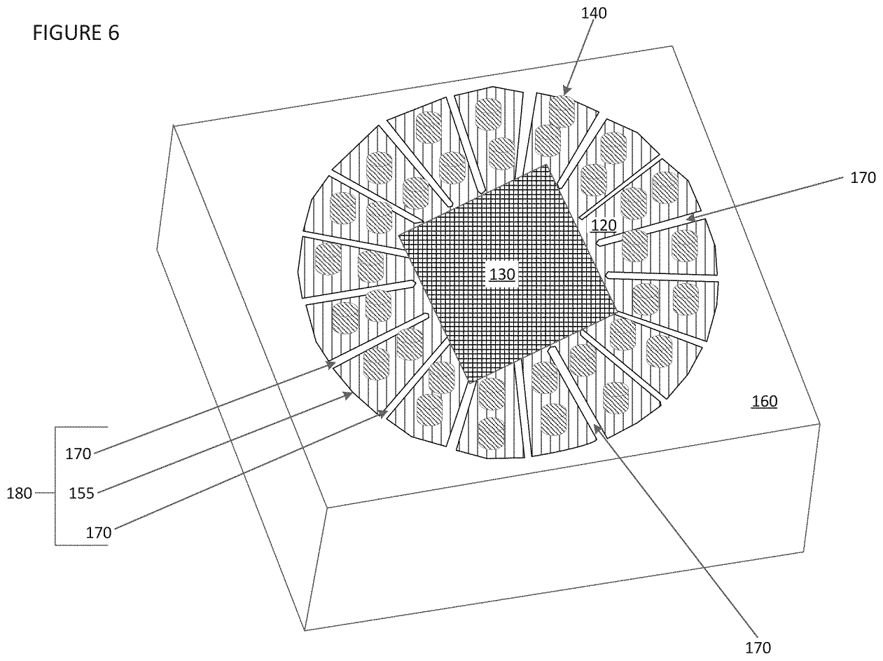

FIG. 6 illustrates the combined interposer 120 and holder 160, in accordance with an embodiment of the present invention.

The interposer 120 and the holder 160 are combined by, for example, the interposer 120 being inserted in to the section 165 of the holder 160. Each vane 170 of the plurality of vanes 170 of the holder 160 corresponds to one of the plurality of grooves 150 in the interposer 120. For example, the interposer 120 can be inserted into the holder 160, so each vane 170 fits in to one of the grooves 150. Any gaps between the vane 170 and the side of interposer 120 along length of the groove 150 could act as a separate microwave cavity. Thus, the fit of the each of the vanes 150 into one grooves 150 should be as exact as possible. Each of the fins 155 of the interposer 120 sits in the second section 175 of the holder 160. Each of the plurality of vanes 170 can be connected to the exposed ground plane 125 of the interposer 120 along the length of each of the grooves 150 by utilizing, for example, wire bond, solder, or other suitable means. Each of the plurality of vanes 170 acts as a side wall of one of the fins 155 when the interposer 120 is inserted in to the holder 160. The width of each of the fins 155 can be the same width as all of the fins 155, at least one of the fins 155, or it can be different from the other fins 155. The plurality of vanes 170 are spaced a part from each other to match the spacing of the grooves 150 in the interposer 120, so that each vane 170 will align with a corresponding groove 150.

A plurality of microwave cavities 180 are created by the insertion of the interposer 120 into the holder 160. Each of the plurality of microwave cavities 180 is defined by one of the fins 170, a first vane 170 acting as one sidewall, and a second vane 170 acting as a second sidewall. A dimension of the microwave cavity 180 can be defined by the fin 155 located on the bottom of the microwave cavity and the two vanes 170 forming the sidewalls of the microwave cavity 180. Each microwave cavity 180 has its own resonance frequency. Therefore, each of the microwave cavities 180 have a lowest standing frequency, i.e., box mode. The box mode for each of the microwave cavities 180 is higher, meaning that the lowest standing frequency is higher than the box mode for an undivided interposer and a holder. The box mode of an undivided interposer and holder limits the frequencies that can be utilized by the different components on the chip and interposer. By increasing the box mode for the combined interposer 120 and holder 160, i.e. the creation of the plurality of microwave cavities 180 that each have a higher box mode allows for components to utilize a greater range of frequencies. The box mode needs to be higher than the operating frequency of the components on the chip 130, the components on the interposer 120, and the coaxial connectors 140. Therefore, the operating frequency of the components on the chip 130 and the interposer 120 can be higher in the combined divided interposer 120 and holder 160, when the components are located in the microwave cavities 180, since the microwave cavities allow for the components to have a higher operating frequency. Thus, by forming each microwave cavity 180 to be much smaller, the local box mode for each cavity allows for components to be located in the microwave cavities 180 and operate at higher frequency than is possible in an undivided interposer and holder combination. Furthermore, when the interposer has fins 155 of different widths that sit in a correspond section 175 of the holder 160, this will create microwave cavities 180 having different dimensions. The dimensions of each microwave cavity 180 determines the box mode for each of the microwave cavities, respectfully. Thus, when there is a first microwave cavity 180 having a first set of dimensions creating a first box mode, and a second microwave cavity 180 having a second set of dimensions creating a second box mode, the first box mode and the second box mode can be different.

Microwaves are utilized during normal operation of the components on the interposer 120. The frequency of the microwave that are utilized for a first component can be the same, different, or at similar microwave frequencies as the microwave frequency utilized by a second component. The different microwave frequencies can cause interference with each other during operation. Since the plurality of vanes 170 are comprised of a conductive material and are connected to ground planes 125, then each of the vanes 170 acts like a barrier to suppress electromagnetic waves generated by components on one of the fins 155 from propagating to the adjacent fin 155 that share the same vane 170 sidewall. Therefore, each of the plurality of the vanes 170 will help to isolate each fin 155 from the electromagnetic waves from a neighboring fin 155.

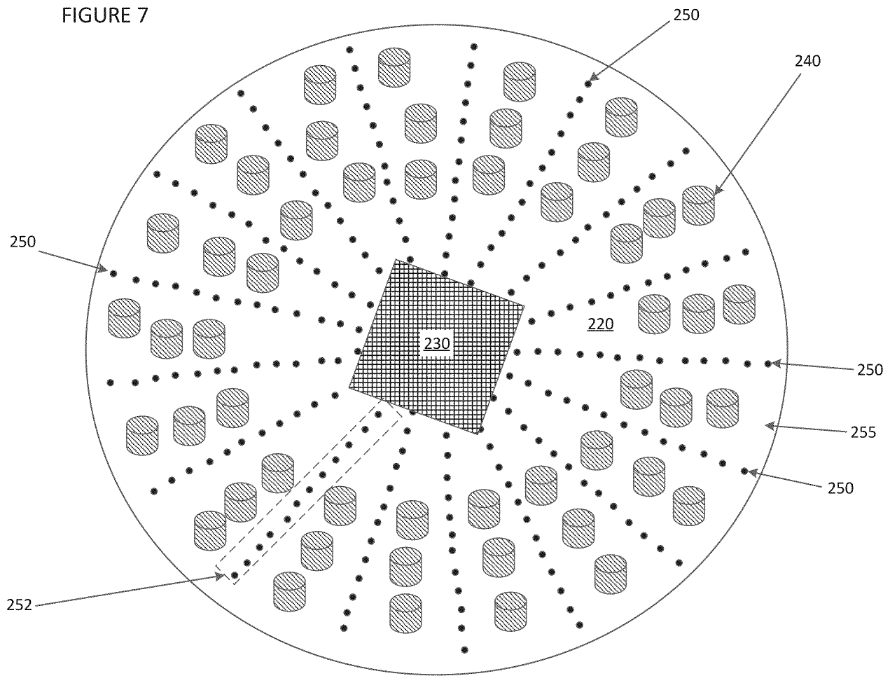

FIG. 7 illustrates a second embodiment of an interposer 220, in accordance with an embodiment of the present invention. The interposer 220 includes a chip 230 and a plurality of coaxial connectors 240. The chip 230 can include any type of electronic components in a singular amount or in a plurality of, for example, capacitors, resistors, transistors, inductors, sensors, antennas, amplifiers, attenuators, diodes, switches, fuses, Josephson junctions, memory, pins, bump bonds, CMOS device, rapid single flux quantum devices (RSFQ), lossy resonators, other types of resonators, a qubit, a Josephson Junction, or any other electrical component, or connection used in creating electrical circuits. The chip 230 can be independently fabricated, in which the different components are formed on the chip 230 prior to the chip 230 being attached on to the interposer 220. Alternatively, the chip 230 can be fabricated (i.e. forming the components) directly on the interposer 220. The chip 230 has electrical wiring/connections (not shown) that fan out from the chip 230 to the plurality of coaxial connectors 240 mounted on the interposer 240. The plurality of coaxial connectors 240 provide the necessary electronic connections to connect the chip 230 to other components located outside the chip 230/interposer 220. The connectors do not have to be coaxial connectors 240, any type of connector will be sufficient as long it provides an electronic connection from the interposer 220 to outside electrical components (not shown). The components mounted on the chip 230, the wiring (not shown) connecting to the plurality of coaxial connectors 240 can have the same operating frequency, different operating frequencies, or any combination of operating frequencies.

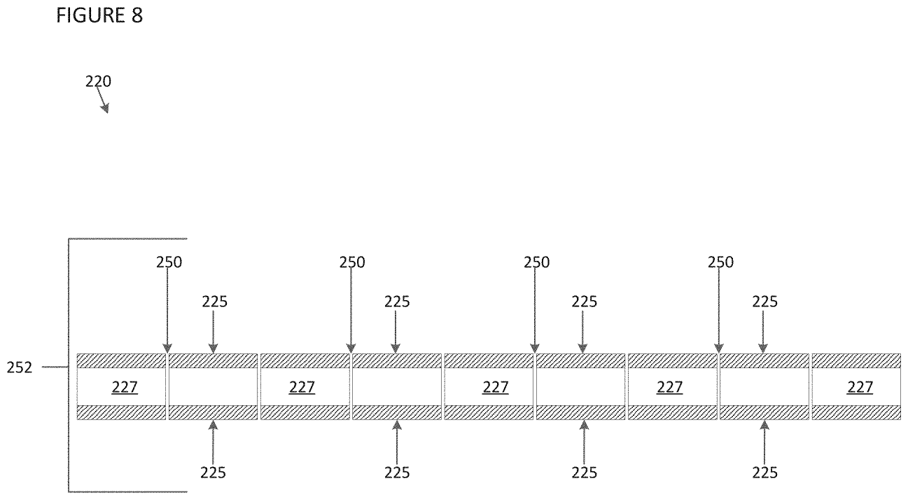

A plurality of holes 250 are machined into the interposer 220. Each of the plurality of holes 250 pass completely through the interposer, as illustrated by FIG. 8. The interposer 220 can be comprised of any suitable material, for example, a silicon wafer. The material of the interposer 220 can be machined to have the plurality of holes 250 after the chip 240 and the plurality of coaxial connectors 240 are mounted on the chip. The plurality of holes 250 can be machined by using, for example, drills, water jets, or any other suitable machining process to fabricate the plurality of holes 250. The plurality of holes 250 are machined into the interposer 220 after the chip 230 had been fabricated and attached to the interposer 220.

A plurality of the holes 250 are arranged in line 252 that extends from a central location of the interposer 220. Each hole 250 is created by removal of material from the interposer 120 at certain locations. The plurality of holes 250 are arranged to form the line 252 that extends from the central location of the interposer 220 to the edge of the interposer 220, and each interposer 220 includes a plurality of lines 252. The interposer 220 includes a substrate 227 and can have a ground plane 225 located on its top surface layer of the substrate 227, bottom surface layer of the substrate 227, as a middle layer in the substrate 227, a different layer, or any combination thereof.

The plurality of lines 252 defines a boundary of a plurality of fins 255 in the interposer 220. Each fin 255 is defined by a central location of the interposer 220, two lines 252 that are spaced apart from each other and extend from the center of the interposer 220 to the edge of the interposer 220. Each of the fins 255 can contain one or more of the coaxial connectors 240, or the fin 255 does not need to contain any of the coaxial connectors 240. The width of each fin 255 can be constant from the central point on the interposer 220 to the edge of the interposer 220. As discussed above, as illustrated by FIG. 2B, the width can be constant along the length of the fin 225. However, the width of the fin 255 can vary, meaning that the plurality of lines 252 extend from the central point on the interposer 220 at an angle, thus the fin 255 will be narrower towards the central point on the interposer 220 and the fin 255 will be wider towards the edge of the interposer 220. As discussed above, as illustrated by FIG. 2C, the width can be varying along the length of the fin 225. The plurality of lines 252 define the width of the fins 255, based on how far apart each line 252 is from another line 252. FIG. 7 illustrates that the width of the fin 255 increases as the fin 255 moves away from the center of the interposer 220. The width of the fin 255 is dependent on the angle/spacing of each of the plurality of lines 252 as the line 252 extend out from the center of the interposer 220. FIG. 7 illustrates that the interposer 120 has a circular shape, however, the interposer 120 can be different shapers, for example, square, rectangle, ellipse, octagon, dodecagon, rhombus, or a different shape. FIG. 7 is only meant to be an example that illustrate the present invention and is not meant to be seen as limiting.

FIG. 8 illustrates an edge of a fin 255 of the interposer 220 along one of the lines 252 of cut holes, in accordance with an embodiment of the present invention. The interposer 220 includes a ground plane 225 and a substrate 227. FIG. 8 illustrates an example of a line 252 of a plurality of holes 250 that exposes a ground plane 225 on top of the substrate 227 and a ground plane 225 on the bottom of the substrate 227 at the located of each hole 250 in the line 252. The location of the ground planes 225 as illustrated by FIG. 8 is only an example and it is not meant to be limiting. Each of the plurality of holes 250 extends through all of the layers of the interposer 220, thus exposing a surface of each of the layers of the interposer 220 along the opening of each of the plurality of holes 250. The ground plane 225 is exposed by the opening of each of the plurality of holes 250 that comprise each line 252, as illustrated by FIG. 8. The spacing of the holes 250 are constant along one line 252, but the spacing of the plurality of holes 250 can vary from one line 252 to another line 252. Each hole 250 is designed to receive a pin 270, which is described below, to fill the hole 250 when the interposer 220 is mounted into the holder 260. This is a method of creating a via post chip 230 fabrication to isolated different sections of the interposer 220 and to break up the box mode of an undivided interposer combined with a holder.

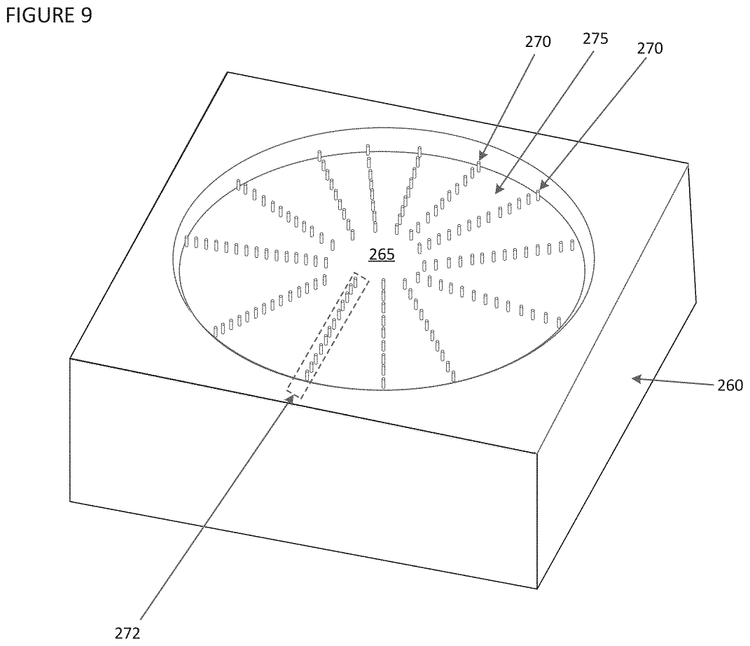

FIG. 9 illustrates a second embodiment a holder 260, in accordance with an embodiment of the present invention.

The holder 260 is comprised of a conductive material, for example, the material can be copper or any other suitable conductive material that can be connected to the ground plane 225 of the interposer 220. The holder includes a section 165 that receives the interposer 220, so that the interposer 220 can be mounted therein. The section 265 includes a plurality of pins 270 that extend up vertically from the bottom of the section 265. The plurality of pins 270 can be the same material as the holder 260 or the plurality of pins 270 can be comprises of a different material. The holder 260 can be machine by, for example, a drill, a water jet, or other suitable means, to create the section 265 and to create the plurality of pins 270. If the plurality of pins 270 are comprised of a different material than the holder 260, then the pins 270 can be mounted to the section 265 of the holder 260, by any suitable means. Each of the plurality of pins 270 of the holder 260 are designed to be aligned with one of the plurality of holes 250 of the interposer 220. A plurality of pins 272 form a row 272. A second section 275 is defined by one row 272 on each side, such that the fin 255 of the interposer 220 will sit within the second section 275 when the interposer 220 is inserted in to the holder 260.

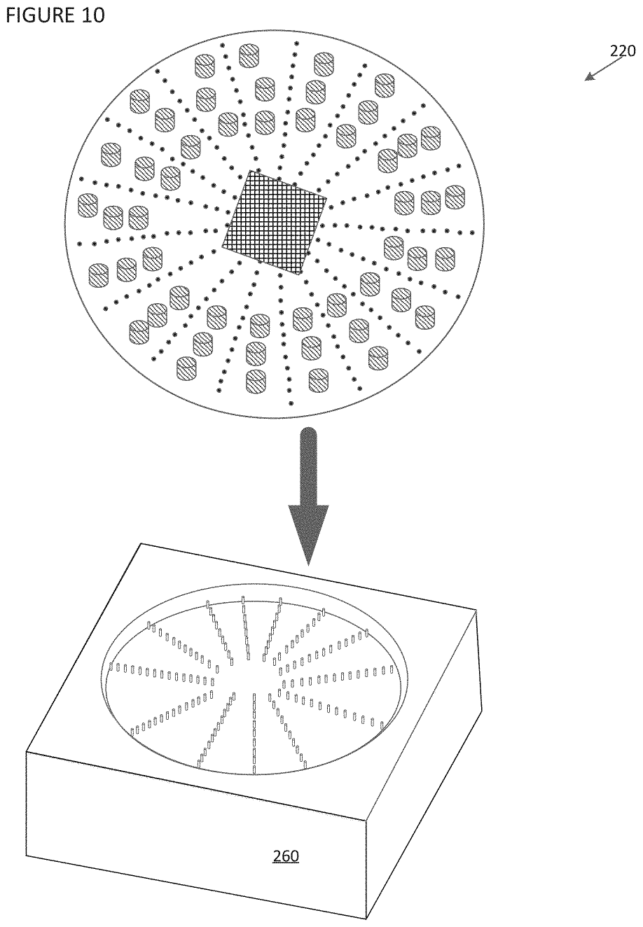

FIG. 10 illustrates the interposer 220 being inserted in the holder 260, in accordance with an embodiment of the present invention. The interposer 220 is first aligned with the holder 220, by matching each line 252 comprised of a plurality of holes 250 to a corresponding row 272 comprised of a plurality of pins 270 in the holder 260 prior the insertion of the interposer 220 in to the holder 260. The rows 272 of pins 270 of holder 260 fit in to a corresponding line 252 of holes 250 in the interposer 220 as the interposer 220 is inserted into section 265 of the holder 260.

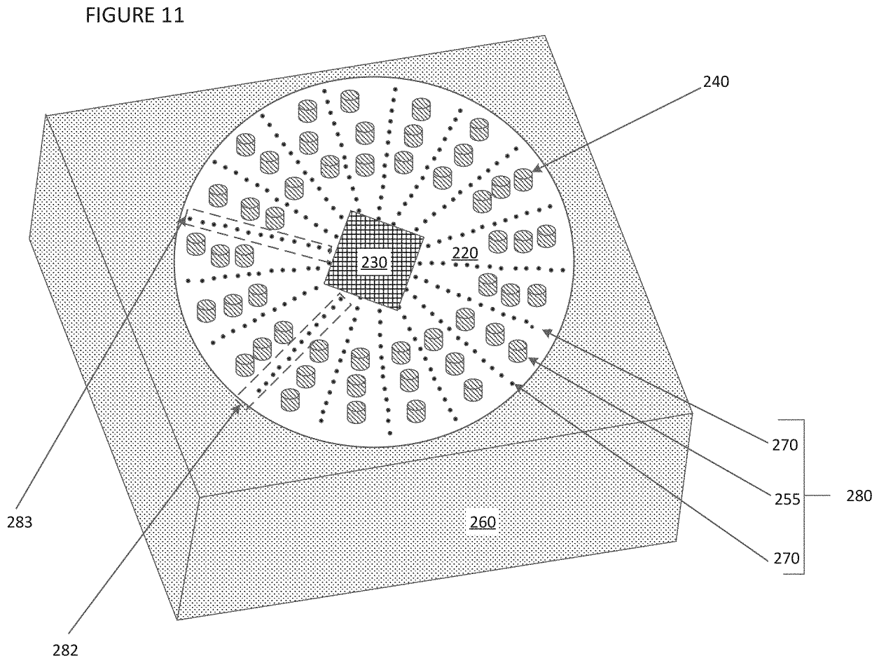

FIG. 11 illustrates the combined interposer 220 and holder 160, in accordance with an embodiment of the present invention. The interposer 220 is first aligned with the holder 260, by matching each line 252 in the interposer 220 to a correspond row 272 in the holder 260 prior the insertion of the interposer 220 in to the holder 160. Each pin 270 of a row 272 in the holder 260 fit in to a corresponding hole 250 in each line 252 in the interposer 220 as the interposer 220 is inserted into section 265 of the holder 260. The fit of one pin 250 into one hole 150 is an exact fit, because if there is air gap between the pin 250 and the side of interposer 220 in the hole 250, the air gap would act as a separate microwave cavity.

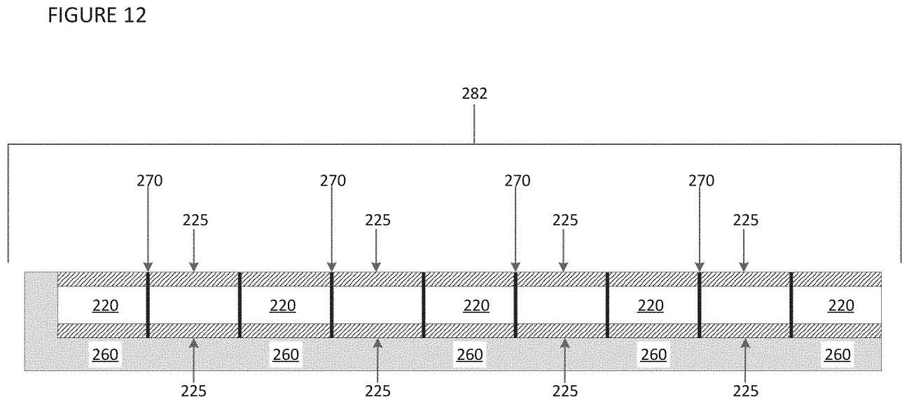

The interposer 220 and the holder 260 are combined by, for example, the interposer 220 being inserted in to the section 265 of the holder 260. A picket fence 282, as illustrated by FIG. 12, is formed when each pin 270 of a row 272 is inserted into a corresponding hole 250 of the plurality of holes 250 that form the line 252. A picket fence 282 is a line of spaced apart vias connected to the exposed ground plane 225 that can suppress electromagnetic wave generated from components on the interposer 220 from propagating from one side of the picket fence 282 to the other side of the picket fence 282. Each of the fins 255 of the interposer 220 sits in the second section 275 of the holder 260. Each of the plurality of pins 270 are connected to the exposed ground plane 225 in one of the plurality of holes 250 of the interposer 220 by utilizing a, for example, wire bond, solder, or other suitable means. Each of the picket fences 282 acts as a side wall of one of the fins 255 when the interposer 220 is inserted in to the holder 260. Each of the fins 255 does not have to be same width as another fin 255, the width of the each of the plurality of fins 255 can be different. The spacing of each of the row 272 just need to match up to a corresponding line 252.

A plurality of microwave cavities 280 are created by the insertion of the interposer 220 into the holder 260. Each of the plurality of microwave cavities 280 is defined by one of the fins 270, a first picket fence 282 (i.e. a row of pins 270 fitted into a line of holes 250) acting as one sidewall, and a second picket fence 282 acting as a second sidewall. Meaning that the dimensions of one of the microwave cavities 280, as defined by, one of the fins 255 and two of the picket fences 282 that form the sidewalls, are smaller than the dimensions of the entire combined interposer 220 and holder 260. Each microwave cavity 280 created by the one of the fins 255 and two of the picket fences 282 sidewalls has its own resonate frequency. The box mode of an undivided interposer and holder limits the frequencies that can be utilized by the different components on the chip and interposer. By increasing the box mode for the combined interposer 220 and holder 260, i.e. the creation of the plurality of microwave cavities 280 that each have a higher box mode, allows for components to utilize a greater range of frequencies. The box mode needs to be higher than the operating frequency of the components on the chip 230, the components on the interposer 220, and the coaxial connectors 240. Therefore, each of the microwave cavities 180 have a lowest standing frequency, i.e., box mode. The box mode for each of the microwave cavities 280 is higher, meaning that the lowest standing frequency is higher, than the box mode for a combined an undivided interposer and a holder. The box mode needs to be higher than the operating frequency of the components on the chip 230, the components on the interposer 220, and the coaxial connectors 240. Therefore, the operating frequency of the components on the chip 230 and the interposer 220 can be higher in the combined divided interposer 220 and holder 260, when the components are located in the microwave cavities 280, since the microwave cavities allow for the components to have a higher operating frequency. Thus, by forming each microwave cavity 280 to be much smaller, the local box mode for each cavity allows for components to be located in the microwave cavities 280 and operate at higher frequency than is possible in an undivided interposer and holder combination. Furthermore, when the interposer has fins 255 of different widths that sit in a correspond section 275 of the holder 260, this will create microwave cavities 280 having different dimensions. The dimensions of each microwave cavity 280 determines the box mode for each of the microwave cavities, respectfully. Thus, when there is a first microwave cavity 280 having a first set of dimensions creating a first box mode, and a second microwave cavity 280 having a second set of dimensions creating a second box mode, the first box mode and the second box mode can be different.

The normal operation of the components on the interposer 220 utilize microwaves to operate, the frequency of the microwave that is utilized for a first component can be the same, different, or at similar microwave frequencies as the microwave frequency utilized by a second component. The different microwave frequencies can cause interference with each other during operations. Since the plurality of pins 270 are comprised of a conductive material and are connected to ground planes 225, then each of the picket fence 282 acts like a barrier and suppress electromagnetic waves generated by components on one of the fins 255 from propagating to the adjacent fin 255 that share the same picket fence 282 sidewall. Therefore, each of the picket fences 282 will help to isolate each fin 255 from the electromagnetic waves from a neighboring fin 255.

The spacing between each of the pins 270 in row 272 and the spacing between each of the corresponding holes 250 in the line 252 affect how much of the electromagnetic propagation that can be suppressed. The spacing of the pins 270 in the picket fence 282 needs to be less than the width of the fin 255. The spacing of the pins 270 in one picket fence 282 needs to be constant the length of the picket fence 282, however, the spacing of the pins 270 of a first picket fence 282 and the spacing of the pins 270 of a second picket fence 283 do not need to be the same. The spacing pins 270 in a picket fence 282 that form one sidewall of the fin 255 does not need to be the same as the space of the pin 270 in the picket fence 282 that form the other sidewall of the fin 255. The spacing of the pins 270 in the picket fence 282, make the picket fence 282 appear solid to the impinging microwaves applied to the interposer 220 and the holder 260.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. An apparatus comprising:
an interposer, wherein the interposer is divided into a plurality of fin sections by a plurality of grooves, wherein a fin of the plurality of fins is defined by a first groove and a second groove, wherein the fin is located between the first groove and the second groove, wherein each groove extends from the center of the interposer to an outer edge of the interposer, wherein each groove exposes the ground plane of the interposer along the length of the groove;
a chip mounted to the interposer; and
a plurality of connecters mounted on the interposer, wherein the plurality of connector electrically connected to chip, wherein at least one connector of the plurality of connectors are mounted in each of the plurality of fin sections.

2. An apparatus comprising:
an interposer mounted to a conductive holder, wherein the silicon interposer is divided into a plurality of fin sections by a plurality of grooves;
the conductive holder includes a first section to receive the interposer; and
the first section includes a plurality of vanes that extends up from the top surface of the first section within the conductive holder, wherein each vane of the plurality of vanes extends through one of the plurality of grooves.

3. The apparatus of claim 2, further comprising:
a chip mounted to the interposer;
a plurality of coaxial connecters mounted on the interposer, wherein the plurality of coaxial connector are electrically connected to chip, wherein at least one coaxial connector of the plurality of coaxial connectors are mounted in each of the plurality of fin sections.

4. The apparatus of claim 2, wherein each groove of the plurality of grooves extends from the center of the interposer to an outer edge of the interposer.

5. The apparatus of claim 4, wherein the spacing between two adjacent grooves of the plurality of grooves defines the width of one of the fin sections of the plurality of fin sections.

6. The apparatus of claim 2, wherein a sidewall of the each of the plurality of fin sections are defined by one of the plurality of grooves.

7. The apparatus of claim 6, wherein each groove extends from the center of the interposer to an outer edge of the interposer.

8. The apparatus of claim 7, wherein each groove of the plurality of grooves exposes a ground plane of the interposer along the length each groove of the plurality of grooves.

9. The apparatus of claim 8, wherein each of the plurality of vanes that extends through each of the plurality of grooves is connected to the ground plane of the interposer.

10. The apparatus of claim 9, further comprising:
a microwave cavity comprised of one fin section of the plurality of fin section having two sidewalls, wherein each sidewall is comprised of one vane of the plurality of vanes that are connected to the ground plane of the interposer.

11. The apparatus of claim 9, further comprising:
a plurality of microwave cavities, wherein each microwave cavity of the plurality of microwave cavities is comprised of one fin section of the plurality of fin sections having two sidewalls, wherein each sidewall is comprised of one vanes of the plurality of vanes that are connected to the ground plane of the interposer.

12. The apparatus of claim 2, wherein the interposer is comprised of a silicon interposer.

13. The apparatus of claim 2, wherein the conductive holder is comprised of copper.

14. An apparatus comprising:
an interposer mounted to a conductive holder; and
a plurality of microwave cavities, wherein each microwave cavity of the plurality of microwave cavities is comprised of a fin section having two sidewalls, wherein each sidewall is comprised of a vane that extends up from the conductive holder through the interposer.

15. The apparatus of claim 14, wherein each vane that extends through the interposer is connected to a ground plane of the interposer.

16. The apparatus of claim 14, wherein the interposer further includes a plurality of grooves, wherein each of the plurality of grooves receives one of the vanes that extends up from the conductive holder.

17. The apparatus of claim 16, wherein each groove of the plurality of grooves extends from the center of the interposer to an outer edge of the interposer.

18. The apparatus of claim 14, further comprising:
a chip mounted to the interposer;
at least one coaxial connecters mounted on the fin section of the interposer, wherein the at least one coaxial connector is electrically connected to chip.
